(19) United States
(12) Patent Application Publication
(10) Pub. No.: US 2026/0052781 A1
(43) Pub. Date: Feb. 19, 2026

(54) FIELD EFFECT TRANSISTOR AND FORMATION METHOD THEREOF

(71) Applicant: TAIWAN SEMICONDUCTOR MANUFACTURING COMPANY, LTD., Hsinchu (TW)

(72) Inventors: Chun-Chen WANG, New Taipei City (TW); Cheng-Chen KUO, Taichung City (TW); Cheng-Hsien WU, Hsinchu City (TW); Chen-Feng HSU, Hsinchu City (TW); Xinyu BAO, Fremont, CA (US)

(73) Assignee: TAIWAN SEMICONDUCTOR MANUFACTURING COMPANY, LTD., Hsinchu (TW)

(21) Appl. No.: 18/802,065

(22) Filed: Aug. 13, 2024

(51) Int. Cl. H01L 29/66; H01L 21/383; H01L 29/786

(52) U.S. Cl. CPC H10D 99/00; H01L 21/383; H10D 30/6713; H10D 30/6734; H10D 30/6755

(57) ABSTRACT

A method of forming a field effect transistor comprises the following steps. A gate dielectric layer and a semiconductor layer are formed over a substrate in sequence. A photoresist layer is formed over the semiconductor layer. A plasma treatment is performed to the semiconductor layer to form a doped region and an undoped region laterally adjoining the doped region of the semiconductor layer using a gas. A conductive layer is formed over the doped region of the semiconductor layer and the photoresist layer. The photoresist layer is lifted off.

### BACKGROUND

Field effect transistors are used in a variety of electronic applications, such as, for example, personal computers, cell phones, digital cameras, and other electronic equipment. Field effect transistors are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flowchart illustrating a method for fabricating a field effect transistor comprising doped regions (shown in FIGS. 2-5) according to various aspects of the present disclosure.

FIGS. 2-5 show schematic cross-sectional views of a field effect transistor at various stages of fabrication according to various aspects of the present disclosure.

FIGS. 6A and 7A show X-ray photoelectron spectroscopy (XPS) curves of S2p and F1s of the semiconductor layer of FIG. 5 which is treated by the plasma treatment, respectively.

FIGS. 6B and 7B show X-ray photoelectron spectroscopy (XPS) curves of S2p and F1s of the semiconductor layer of FIG. 5 being annealed after performing the plasma treatment PT.

FIG. 8 is a plot of gate voltage (V_{g}) versus drain current (I_{d}) for the field effect transistor in FIG. 5 and a comparable example in an off-state according to some embodiments of the present disclosure.

FIG. 9A is a field effect transistor similar to the field effect transistor in FIG. 5, except for the plasma treatment being performed to the region uncovered by the second portion of the conductive layer.

FIG. 9B is a field effect transistor similar to the field effect transistor in FIG. 5, except for the plasma treatment being performed to the entire top surface of the semiconductor layer.

FIG. 10A is a field effect transistor similar to the field effect transistor in FIG. 5, except for the field effect transistor further comprising a gate electrode between the substrate and the first gate dielectric layer.

FIG. 10B is a field effect transistor similar to the field effect transistor in FIG. 5, except for the field effect transistor further comprising a gate electrode between the substrate and the first gate dielectric layer.

FIG. 11 is a flowchart illustrating a method for fabricating a field effect transistor comprising doped regions (shown in FIGS. 12-16) according to various aspects of the present disclosure.

FIGS. 12-16 show schematic cross-sectional views of a field effect transistor 200 at various stages of fabrication according to various aspects of the present disclosure.

FIGS. 17-19 show schematic cross-sectional views of a field effect transistor at various stages of fabrication according to various aspects of the present disclosure.

FIG. 20 is a field effect transistor similar to the field effect transistor in FIG. 19, except for the field effect transistor further comprising a gate electrode between the substrate and the first gate dielectric layer.

FIG. 21 is a field effect transistor similar to the field effect transistor in FIG. 19, except for the field effect transistor further comprising a gate electrode between the substrate and the first gate dielectric layer.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 230 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. In this disclosure, a source/drain refers to a source and/or a drain. It is noted that in the present disclosure, a source and a drain are interchangeably used and the structures thereof are substantially the same.

Oxide semiconductors are promising channel material for transistors due to their compatibility with back-end-of-line (BEOL) process. However, achieving performance parity between p-type and n-type oxide devices remains a challenge. One issue is that source/drain contacts are often formed directly on the channel layer without prior etching or treating, leading to rough interfaces and potential air gaps between the source/drain contacts and the channel layer. These deficiencies may lead to increased drain current in an off-state as a gate voltage increases positively, which is phenomenon known as ambipolar effect or ambipolar behavior. The ambipolar effect in the p-type oxide semiconductor arises from the material's ability to exhibit both p-type and n-type conductivity due to various oxidation states. This dual polarity is problematic for complementary metal-oxide-semiconductor (CMOS) device operation, as it can degrade the performance and efficiency of p-type MOS (PMOS) transistors.

To address this issue, the present disclosure in various embodiments provides a method of performing a plasma treatment to source/drain contact area of a semiconductor layer prior to depositing a conductive layer. This treatment results in a smoothened interface between the conductive layer and the channel layer, thereby suppressing the ambipolar effect in the p-type semiconductor transistors. Drain current can thus remain low in the off-state, leading to improved performance and efficiency in CMOS device operation.

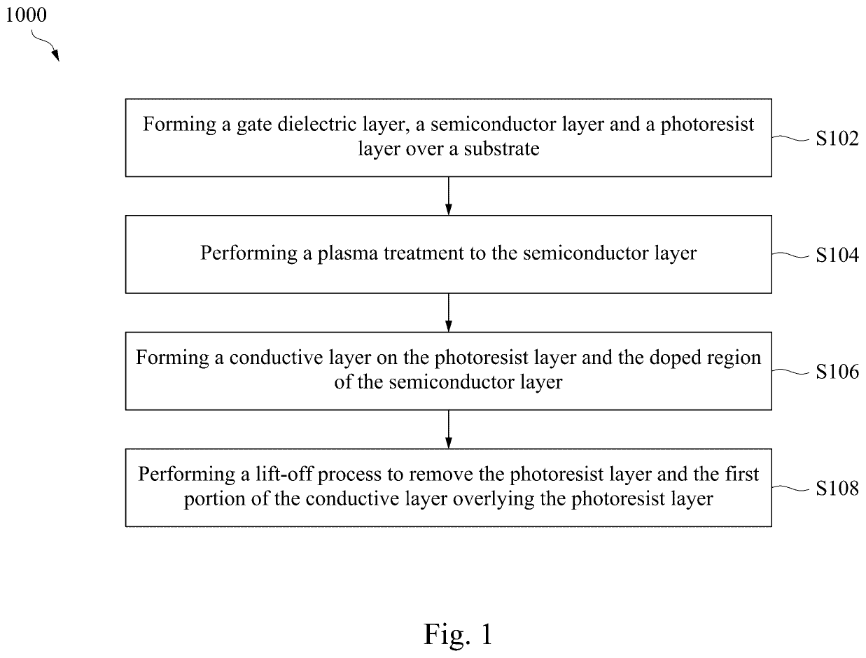

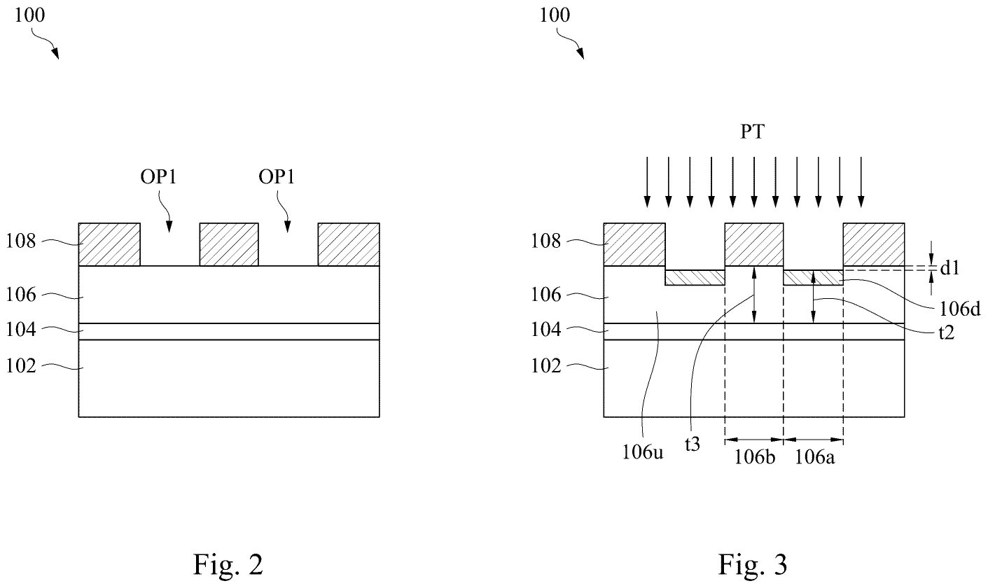

FIG. 1 is a flowchart illustrating a method 1000 for fabricating a field effect transistor comprising doped regions (shown in FIGS. 2-5) according to various aspects of the present disclosure. FIGS. 2-5 show schematic cross-sectional views of a field effect transistor 100 at various stages of fabrication according to various aspects of the present disclosure. As employed in the present disclosure, the term field effect transistor 100 refers to a planar metal-oxide-semiconductor field effect transistor (MOSFET). Other transistor structures and analogous structures, such as fin field effect transistor (FinFET), gate-all-around (GAA) field effect transistor or tunneling field effect transistor (TFET), are within the contemplated scope of the disclosure. The field effect transistor 100 may be included in a microprocessor, memory cell, and/or other integrated circuit (IC).

The field effect transistor 100 of FIG. 2 may be further processed using CMOS technology processing. Accordingly, it is understood that additional processes may be provided before, during, and after the method 100 0 of FIG. 1, and that some other processes may only be briefly described herein. Also, FIGS. 2-5 are simplified for a better understanding of the concepts of the present disclosure. For example, it is understood the field effect transistor 100 may be part of an IC that further comprises a number of other devices such as resistors, capacitors, inductors, fuses, etc.

Referring to FIG. 1, the method 1000 begins at a step S102 wherein a gate dielectric layer, a semiconductor layer and a photoresist layer are formed over a substrate in sequence. Referring to FIGS. 1 and 2, the method 1000 begins at the step S102 wherein a first gate dielectric layer 104, a semiconductor layer 106 and a photoresist layer 108 are formed over a substrate 102 in sequence. In at least one embodiment, the substrate 102 may include a silicon substrate. In some alternative embodiments, the substrate 102 may be made of some other suitable elemental semiconductor, such as diamond or germanium; a suitable compound semiconductor, such as gallium arsenide, silicon carbide, indium arsenide, or indium phosphide; or a suitable alloy semiconductor, such as silicon germanium carbide, gallium arsenic phosphide, or gallium indium phosphide. The substrate 102 may further include other features such as various doped regions, a buried layer, and/or an epitaxy layer. Furthermore, the substrate 102 may be a semiconductor on insulator such as silicon on insulator (SOI) or silicon on sapphire. In some other embodiments, the substrate 102 may include a doped epitaxial layer, a gradient semiconductor layer, and/or may further include a semiconductor layer overlying another semiconductor layer of a different type such as a silicon layer on a silicon germanium layer. In other examples, a compound semiconductor substrate 102 may include a multilayer silicon structure or a silicon substrate may include a multilayer compound semiconductor structure. In some embodiments, the substrate 102 is a heavily doped silicon substrate including p-type dopants such as boron or BF₂ or n-type dopants such as phosphorus or arsenic and has low resistivity. In some embodiments, the substrate 102 can be a silicon substrate with a metal layer formed thereon (not separately illustrated). In some embodiments, the substrate 102 includes insulator material such as plastic.

In some embodiments, the substrate 102 may further include active regions and isolation regions (not shown). The active regions may include various doping configurations depending on design requirement. In some embodiments, the active region may be doped with p-type or n-type dopants. The active regions may be configured for an N-type metal-oxide-semiconductor field effect transistor (referred to as an NMOSFET), or alternatively configured for a P-type metal-oxide-semiconductor field effect transistor (referred to as a PMOSFET).

In some embodiments, the isolation regions may be formed on the substrate 102 to isolate the various active regions. The isolation regions may utilize isolation technology, such as local oxidation of silicon (LOCOS) or shallow trench isolation (STI), to define and electrically isolate the various active regions. In at least one embodiment, the isolation region includes an STI. The isolation regions may include silicon oxide, silicon nitride, silicon oxynitride, fluoride-doped silicate glass (FSG), a low-k dielectric material, other suitable materials, and/or combinations thereof. The isolation regions, and in the present embodiment, the STI, may be formed by any suitable process. As one example, the formation of the STI may include patterning the substrate 102 by a conventional photolithography process, etching a trench in the substrate 102 (for example, by using a dry etching, wet etching, and/or plasma etching process), and filling the trench (for example, by using a chemical vapor deposition process) with a dielectric material. In some embodiments, the filled trench may have a multi-layer structure such as a thermal oxide liner layer filled with silicon nitride or silicon oxide.

Then, the first gate dielectric layer 104 is formed over the substrate 102. In some embodiments, the first gate dielectric layer 104 may include silicon oxide, silicon nitride, high-k dielectric material or a multilayer dielectric thereof. A high-k dielectric material is defined as a dielectric material with a dielectric constant greater than that of SiO₂. The high-k dielectric material can include metal oxide. In some embodiments, the metal oxide is selected from the group consisting of oxides of Li, Be, Mg, Ca, Sr, Sc, Y, Zr, Hf, Al, La, Ce, Pr, Nd, Sm, Eu, Gd, Tb, Dy, Ho, Er, Tm, Yb, Lu, or mixtures thereof. The first gate dielectric layer 104 may be grown by a thermal oxidation process, a chemical vapor deposition (CVD) process, an atomic layer deposition (ALD) process or other suitable deposition methods.

In some embodiments, the first gate dielectric layer 104 may further include an interfacial layer (not shown) to minimize stress between the first gate dielectric layer 104 and the substrate 102. The interfacial layer may be formed of silicon oxide or silicon oxynitride grown by a thermal oxidation process. For example, the interfacial layer can be grown by a rapid thermal oxidation (RTO) process or in an annealing process including oxygen.

Then, the semiconductor layer 106 is formed on the gate dielectric layer 104 and can include a p-type oxide semiconductor material. For example, the semiconductor layer can be a p-type oxide semiconductor layer, such as a p-type metal oxide layer. In other words, the semiconductor layer can be a p-type oxide semiconductor. The p-type oxide semiconductor is metal-ion-deficient, and the majority of charge carriers are holes (h+). The p-type oxide semiconductor valence band maximum (VBM) has enhanced energy band dispersion owing to the presence of metal atomic orbitals and O 2p orbital hybridization, leading to an increase in carrier mobility. The semiconductor layer 106 acts as a channel layer of the field effect transistor 100. In some embodiments, the semiconductor layer 106 includes SnOₓ, CuOₓ, NiOₓ, the like, or a combination thereof.

The photoresist layer 108 is then formed and patterned on the semiconductor layer 106. The photoresist layer 108 may be formed by spin-coating or the like and may be exposed to light for patterning. The patterning forms openings OP1 through the photoresist layer 108 to expose the semiconductor layer 106. Exposed regions of the semiconductor layer 106 can be referred to contact areas to contact a subsequently formed source/drain electrode.

Referring to FIGS. 1 and 3, the method 1000 continues with a step S104 in which a plasma treatment PT is performed to the semiconductor layer 106. The plasma treatment can be performed using gas such as SF₆, CH₂F₂, BCl₃, Ar, N₂, the like, or a combination thereof. In some embodiments where the plasma treatment PT is performed using SF₆ gas, sulfur (S) atoms and fluorine (F) atoms from the SF₆ gas may be doped into the exposed region, forming a doped region 106d while leaving an undoped region 106u laterally adjoining the doped region 106d. In the doped region 106d, S atoms, F atoms or a combination thereof exist therein. Therefore, F—Sn bonding, S—Sn bonding, or a combination thereof exists in the doped region 106d. In some embodiments where the plasma treatment PT is performed using CH₂F₂ gas, in the doped region 106d, C atoms, H atoms, F atoms, or a combination thereof exist therein. Therefore, C—Sn bonding, H—Sn bonding, F—Sn bonding, or a combination thereof can be detected in the doped region 106d. In some embodiments where the plasma treatment PT is performed using BCl₃ gas, in the doped region 106d, B atoms, Cl atoms, or a combination thereof exist therein. Therefore, B—Sn bonding, Cl—Sn bonding, or a combination thereof can be detected in the doped region 106d. In some embodiments where the plasma treatment PT is performed using Ar gas, Ar atoms exist therein. In some embodiments where the plasma treatment PT is performed using N₂ gas, in the doped region 106d, N atoms exist therein. Therefore, N—Sn bonding can be detected.

In some embodiments, the concentration of the doped atoms in the doped region 106d can vary depending on the specific conditions of the plasma treatment PT, such as the duration of the treatment, the power of the plasma, and the pressure of the gas. For instance, higher plasma power or longer treatment duration can result in a higher concentration of doped atoms. Conversely, lower plasma power or shorter treatment duration can result in a lower concentration of doped atoms. Furthermore, the concentration gradient of the doped atoms may also vary, with higher concentrations near the surface of the semiconductor layer 106 and gradually decreasing concentrations deeper into the semiconductor layer 106.

In some embodiments, due to the semiconductor layer 106 being etchable to the plasma treatment PT, the exposed region of the semiconductor layer 106 is etched by the plasma treatment PT. Therefore, the semiconductor layer 106 can include a first portion 106a exposed by the photoresist layer 108 having a first thickness t1 and a second portion 106b covered by the photoresists layer 108 having a second thickness t2 different from the first thickness t1 along a direction substantially vertical to a top surface of the substrate 102. For example, first thickness t1 is less than the second thickness. In other words, the first portion 106a is thinner than the second portion 106b. The doped region 106d and the undoped region 106u have top surfaces at different heights. For example, the doped region 106d has a top surface lower than a top surface of a region of the semiconductor layer 106 covered by the photoresist layer 108 by a distance d1. Due to the plasm a treatment PT, the doped region 106d can have a smooth surface, which is beneficial to form a smooth interface with a subsequently formed conductive layer.

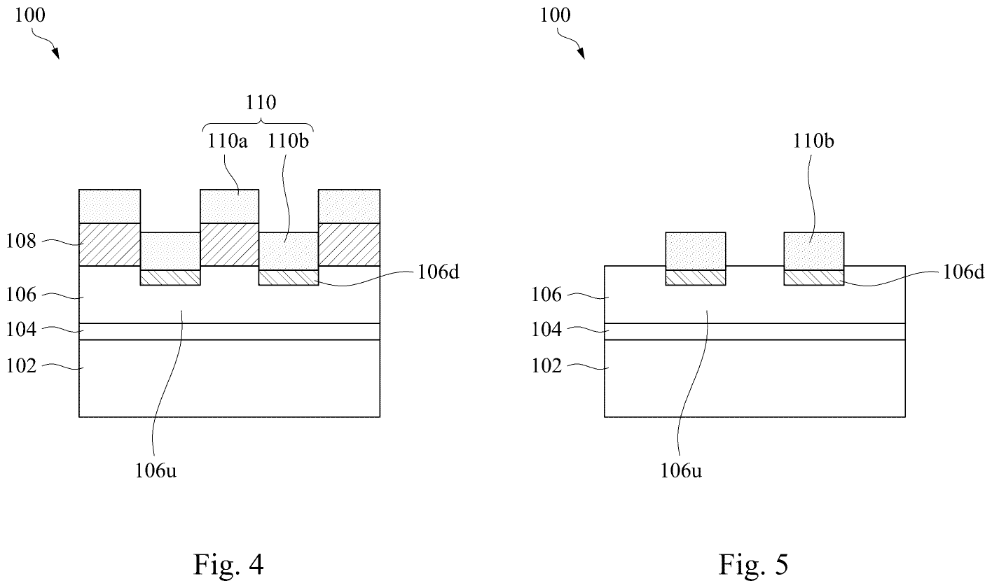

Referring to FIGS. 1 and 4, the method 1000 continues with a step S106 in which a first conductive layer 110 is formed on the photoresist layer 108 and the doped region 106d of the semiconductor layer 106. For example, the first conductive layer 110 has a first portion 110a over the photoresist layer 108 and a second portion 110b over the doped region 106d of the semiconductor layer 106. In some embodiments, the first conductive layer 110 can be a metal layer, and can be a single layer or a multilayer. For example, the first conductive layer 110 can include Ni, indium tin oxide (ITO), Ti/Au, Ti/Al/Ni/Au, the like, or a combination thereof. In some embodiments, the first conductive layer 110 can be formed by CVD, physical vapor deposition (PVD) , plating, ALD, or other suitable technique. An interface between the second portion 110b of the first conductive layer 110 and the doped region 106d of the semiconductor layer 106 can be improved and smooth. The interface between the second portion 110b of the first conductive layer 110 and the channel (i.e., the source/drain contact area of the semiconductor layer 106) can be improved and smooth. In some embodiments where the semiconductor layer 106 is a p-type semiconductor layer, the field effect transistor 100 can serve as a p-type field effect transistor. Due to the improved and smooth interface, the ambipolar effect in the field effect transistor 100 can be reduced or suppressed. Drain current can thus remain low in the off-state. For the field effect transistor 100 involved in a complementary metal oxide semiconductor (CMOS) device operation, improved performance and efficiency is achieved.

Referring to FIGS. 1 and 5, the method 1000 continues with a step S108 in which a lift-off process is performed to remove the photoresist layer 108 and the first portion 110a of the first conductive layer 110 overlying the photoresist layer 108. For example, in the lift-off process, the photoresist layer 108 is etched by an etchant. In some embodiments, the etchant includes an organic solvent that attacks the photoresist layer 108 but not the first conductive layer 110. The etching of the photoresist layer 108 lifts off the overlying first conductive layer 110 (i.e., the first portion 110a) over the photoresist layer 108. As a result, the first portion 110a of the first conductive layer 110 is removed. The second portion 110b of the first conductive layer 110 remains over the doped region 106d of the semiconductor layer 106 and serves as source/drain electrodes. The doped region 106d can overlap the second portion 110b of the first conductive layer 110. In some embodiments, after performing the lift-off process, an anneal process is performed to the field effect transistor 100 to tune electrical properties of the semiconductor layer. For example, a hole mobility of the semiconductor layer 106 can be increased by the anneal process.

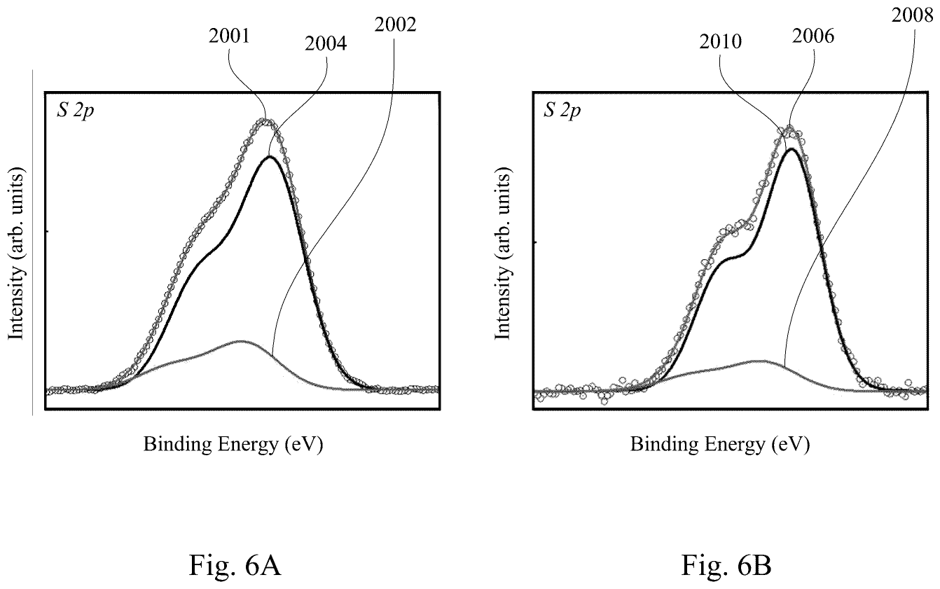

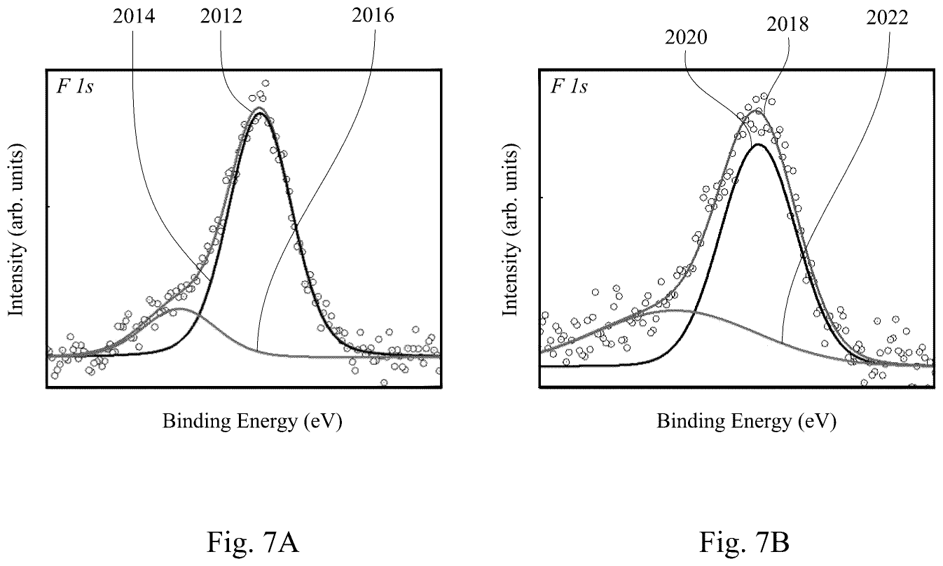

FIGS. 6A and 7A show X-ray photoelectron spectroscopy (XPS) curves of S2p and F1s of the semiconductor layer 106 of FIG. 5 which is treated by the plasma treatment PT, respectively. FIGS. 6B and 7B show X-ray photoelectron spectroscopy (XPS) curves of S2p and F1s of the semiconductor layer 106 of FIG. 5 being annealed after performing the plasma treatment PT. In some embodiments, in FIGS. 6A and 6B, the measurement condition of XPS can include using X-ray source of 775±100 eV. In FIG. 6A, XPS curve 2001 can be divided into peak 2002 and peak 2004 which indicate S—O/F bonding and S—Sn bonding, respectively. Ratios of intensity areas of the peak 2002 and the peak 2004 in the XPS curve 2001 can be 17.9±5% and 82.1±5%, respectively. In FIG. 6B, XPS curve 2006 can be divided into peak 2008 and peak 2010 which indicate S—O/F bonding and S—Sn bonding, respectively. Ratios of intensity areas of the peak 2008 and the peak 2010 in the XPS curve 2006 can be 12.5±5% and 87.5±5%, respectively.

In some embodiments, in FIGS. 7A and 7B, the measurement condition of XPS can include using X-ray source of 1050±100 eV. In FIG. 7A, XPS curve 2012 can be divided into peak 2014 and peak 2016 which indicate F—O/C bonding and F—Sn bonding, respectively. In FIG. 7B, XPS curve 2018 can be divided into peak 2020 and peak 2022 which indicate F—O/C bonding and F—Sn bonding, respectively. Ratios of intensity areas of the peak 2014 and the peak 2016 in the XPS curve 2012 can be 18.7±5% and 81.3±5%. Ratios of intensity areas of the peak 2020 and the peak 2022 in the XPS curve 2018 can be 34.7±5% and 65.3±5%.

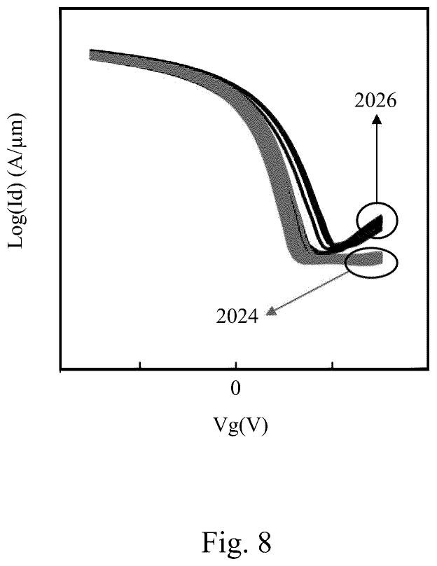

FIG. 8 is a plot of gate voltage (V_{g}) versus drain current (I_{d}) for the field effect transistor 100 in FIG. 5 and a comparable example in an off-state according to some embodiments of the present disclosure. Reference is made to FIG. 8. Curves 2024 and 2026 indicate the field effect transistor 100 and the comparable example, respectively. The ambipolar effect of the field effect transistor 100 is reduced because the interface between the second portion 110b of the first conductive layer 110 and the doped region 106d of the semiconductor layer 106 can be improved and smooth. For the curve 2024, the drain current in the off-state is suppressed and does not increase when the gate voltage increases positively. By contrast, in the curve 2026 which the comparable does not undergo the step S104, the drain current increases when the voltage increases positively.

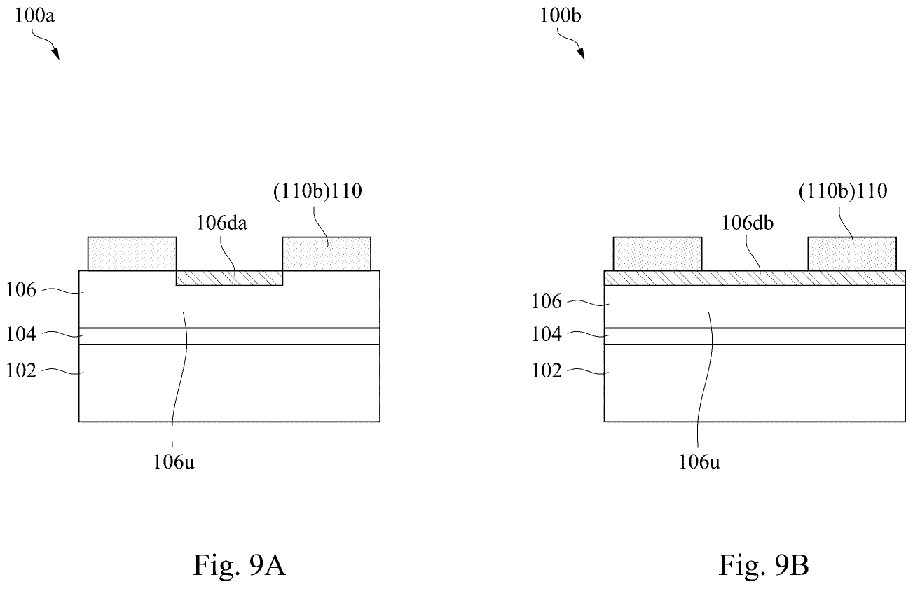

FIG. 9A is a field effect transistor 100a similar to the field effect transistor 100 in FIG. 5, except for the plasma treatment being performed to the region uncovered by the second portion 110b of the first conductive layer 110. That is, the doped region 106da non-overlaps the second portion 110b of the first conductive layer 110. Therefore, the doped region 106da is between the second portions 110b of the first conductive layer 110. As discussed above, due to the plasma treatment, the doped region 106da can have a smooth surface, which is beneficial to form a smooth interface with a subsequently formed layer.

FIG. 9B is a field effect transistor 100b similar to the field effect transistor in FIG. 5, except for the plasma treatment being performed to the entire top surface of the semiconductor layer 106. Therefore, the doped region 106db spans under the second portion 110b of the first conductive layer 110 and is between the second portions 110b of the first conductive layer 110. That is, the doped region 106db can overlap the second portion 110b of the first conductive layer 110. As discussed above, due to the plasma treatment, the doped region 106db can have a smooth surface, which is beneficial to form a smooth interface with a subsequently formed layer.

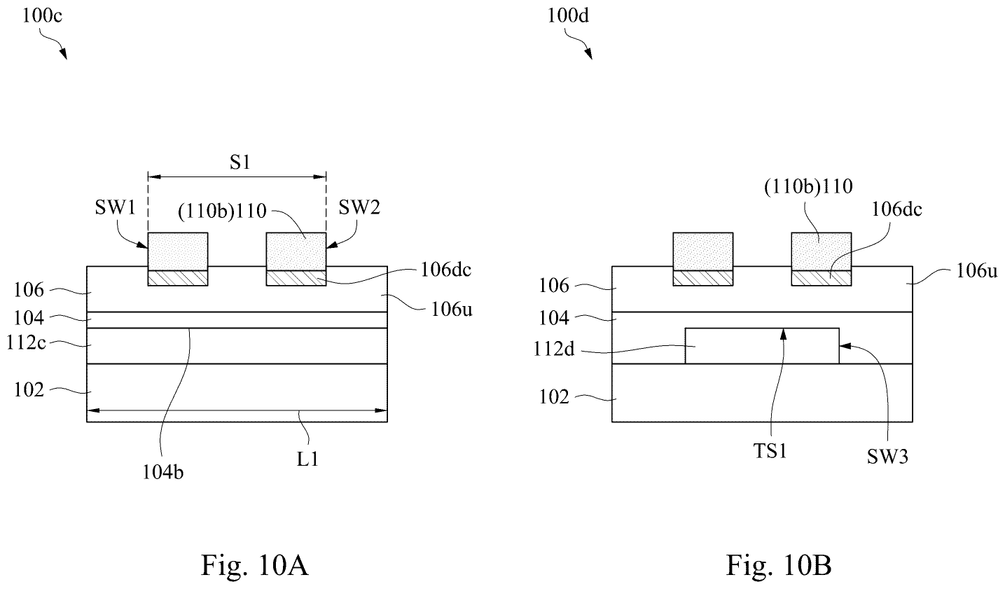

FIG. 10A is a field effect transistor 100c similar to the field effect transistor 100 in FIG. 5, except for the field effect transistor 100c further comprising a gate electrode 112c between the substrate 102 and the first gate dielectric layer 104. For example, the gate electrode 112c extends along an entire bottom surface 104b of the first gate dielectric layer 104. The gate electrode 112c can be referred to as a global gate since the gate electrode 112c can have a length L1 longer than a spacing S1 between sidewalls SW1, SW2 of the two neighboring second portions 110b of the first conductive layer 110 facing away from each other. In some embodiments, the gate electrode 112c overlaps the doped region 106dc.

FIG. 10B is a field effect transistor 110d similar to the field effect transistor 100 in FIG. 5, except for the field effect transistor 110d further comprising a gate electrode 112d between the substrate 102 and the first gate dielectric layer 104. For example, the gate electrode 112d overlaps a region of the semiconductor layer 106 between the two neighboring ones of the second portion 110b of the first conductive layer 110. That is, the gate electrode 112d has opposite sidewalls SW3 and a top surface TS1 covered by the first gate dielectric layer 104. The gate electrode 112d can be referred to as a local gate.

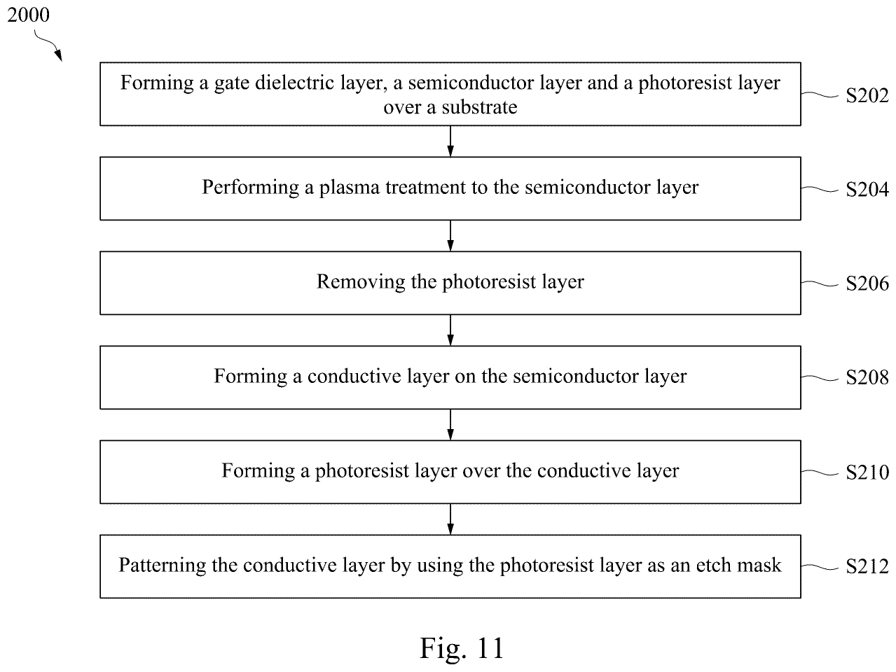

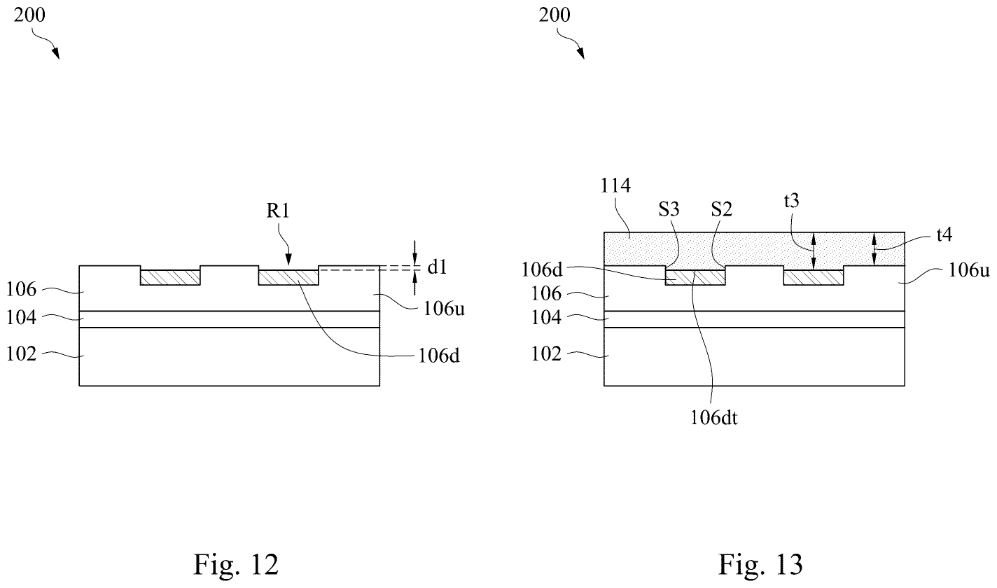

FIG. 11 is a flowchart illustrating a method 2000 for fabricating a field effect transistor 200 comprising doped regions 106d (shown in FIGS. 12-16) according to various aspects of the present disclosure. FIGS. 12-16 show schematic cross-sectional views of a field effect transistor 200 at various stages of fabrication according to various aspects of the present disclosure. As employed in the present disclosure, the term field effect transistor 200 refers to a planar metal-oxide-semiconductor field effect transistor (MOSFET). Other transistor structures and analogous structures, such as fin field effect transistor (FinFET), gate-all-around (GAA) field effect transistor or tunneling field effect transistor (TFET), are within the contemplated scope of the disclosure. The field effect transistor 200 may be included in a microprocessor, memory cell, and/or other integrated circuit (IC).

The field effect transistor 200 of FIG. 12 may be further processed using CMOS technology processing. Accordingly, it is understood that additional processes may be provided before, during, and after the method 2000 of FIG. 11, and that some other processes may only be briefly described herein. Also, FIGS. 12-16 are simplified for a better understanding of the concepts of the present disclosure. For example, it is understood the field effect transistor 200 may be part of an IC that further comprises a number of other devices such as resistors, capacitors, inductors, fuses, etc.

Referring to FIG. 11, the method 2000 begins at step S202 wherein a photoresist layer, a semiconductor layer and a gate dielectric layer are formed over a substrate, which is similar to the step S102 of the method 1000 in FIG. 1. The method 2000 continues with a step S204 in which a plasma treatment is performed to the semiconductor layer 106, which is similar to the step S104. Referring to FIGS. 11 and 12, the method 2000 continues with a step S206 in which the photoresist layer (see FIG. 3) is removed by suitable method, such as wet stripping or plasma ashing. The doped region 106d and the undoped region 106u of the semiconductor layer 106 are exposed. As discussed above, the doped region 106d has a top surface lower than a top surface of the undoped region 106u by a distance d1. That is, a recess R1 may be formed over the doped region 106d.

Referring to FIGS. 11 and 13, the method 2000 continues with a step S208 wherein a conductive layer is formed on the semiconductor layer. The first conductive layer 114 fills into the recess R1 and covers the top surface of the semiconductor layer 106. For example, the first conductive layer 114 can be in contact with opposite sidewalls S2, S3 of the undoped region of the semiconductor layer 106 and in contact with a top surface 106dt of the doped region 106d of the semiconductor layer 106. That is, the first conductive layer 114 has a first thickness t3 over the doped region 106d and a second thickness t4 over the undoped region 106u less than the first thickness t3. The first conductive layer 114 is similar to the first conductive layer 110 with regard to FIG. 4 in terms of composition and formation method, and thus the description thereof is omitted herein.

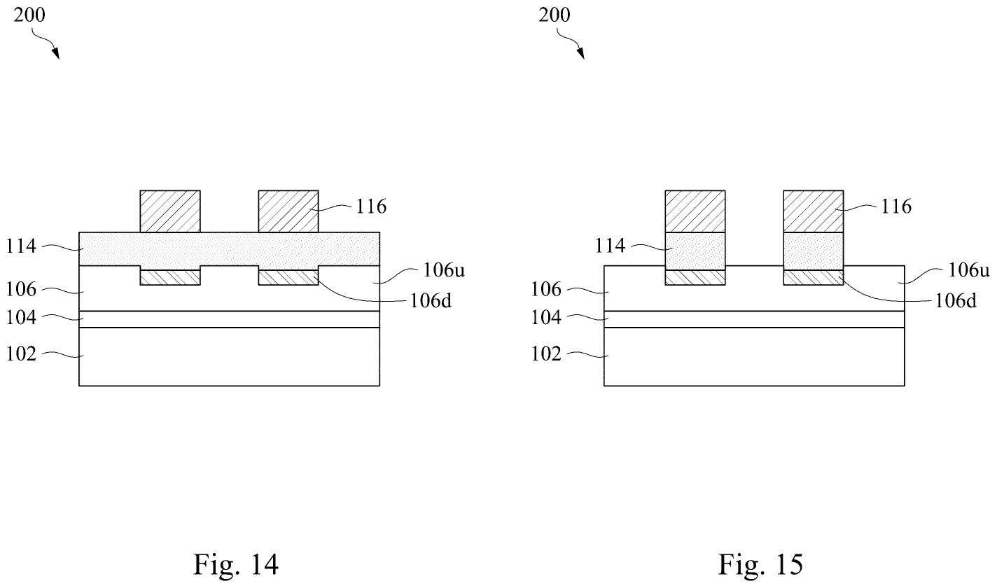

Referring to FIGS. 11 and 14, the method 2000 continues with a step S210 wherein a photoresist layer 116 is formed over the first conductive layer 114. In some embodiments, the photoresist layer 116 may be formed by spin-coating or the like and may be exposed to light for patterning. The patterning forms openings through the photoresist layer 116 to expose the first conductive layer 114. In some embodiments, the photoresist layer 116 overlaps the doped region 106d.

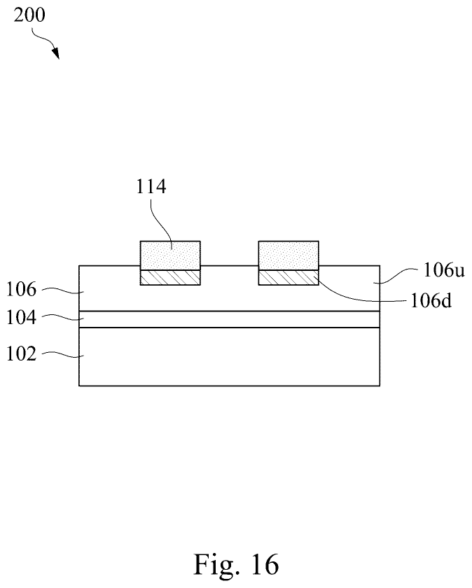

Referring to FIGS. 11 and 15, the method 2000 continues with a step S212 wherein the conductive layer 114 is patterned by using the photoresist layer 116 as an etch mask, leaving the conductive layer 114 overlapping the doped region 106d. In some embodiments, a dry (or plasma) etch is applied to remove the conductive layer 114 within the openings of the photoresist layer 116. The photoresist layer 116 is thereafter removed using a suitable process, such as wet stripping or plasma ashing. The resulting structure is shown in FIG. 16.

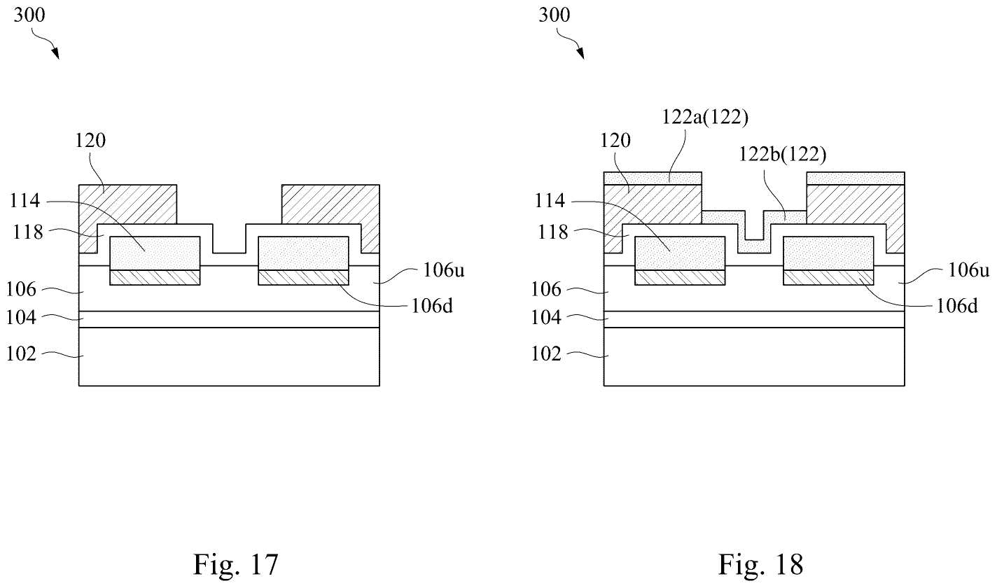

FIGS. 17-19 show schematic cross-sectional views of a field effect transistor 300 at various stages of fabrication according to various aspects of the present disclosure. The field effect transistor 300 in FIG. 17 is similar to the field effect transistor 100 in FIG. 5, and continues with formation of a second gate dielectric layer 118 over the first conductive layer 114 and the semiconductor layer 106. In some embodiments, the second gate dielectric layer 118 is similar to the first gate dielectric layer 104 in terms of composition and formation method, and thus the description thereof is omitted herein.

Reference is made to FIG. 18. In some embodiments, a second conductive layer 122 may be formed over the photoresist layer 120 and the second gate dielectric layer 118. In some embodiments, the second conductive layer 122 is similar to the first conductive layer 114 in terms of composition and formation method, and thus the description thereof is omitted herein. The second conductive layer 122 can act as a top gate electrode. In some embodiments, the second conductive layer 122 may have a first portion 122a over the photoresist layer 120 and a second portion 122b over the second gate dielectric layer 118. In other words, the second portion 122b of the second conductive layer 122 overlaps the second gate dielectric layer 118.

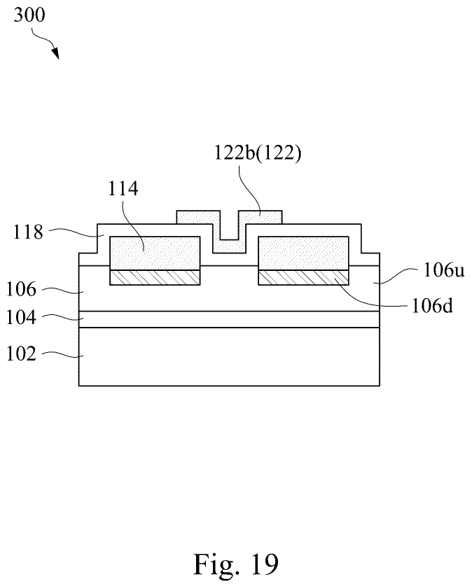

Reference is made to FIG. 19. A lift-off process is performed to remove the photoresist layer 120 and the first portion 122a of the second conductive layer 122 overlying the photoresist layer 120. For example, in the lift-off process, the photoresist layer 120 is etched by an etchant. In some embodiments, the etchant includes an organic solvent that attacks the photoresist layer 120 but not the second conductive layer 122. The etching of the photoresist layer 120 lifts off the overlying second conductive layer 122 (i.e., the first portion 122a) over the photoresist layer 120. As a result, the first portion 122a of the second conductive layer 122 is removed. The second portion 122b of the second conductive layer 122 remains over the second gate dielectric layer 118 and serves as a top gate electrode. The doped region 106d can partially overlap the second portion 122b of the second conductive layer 122.

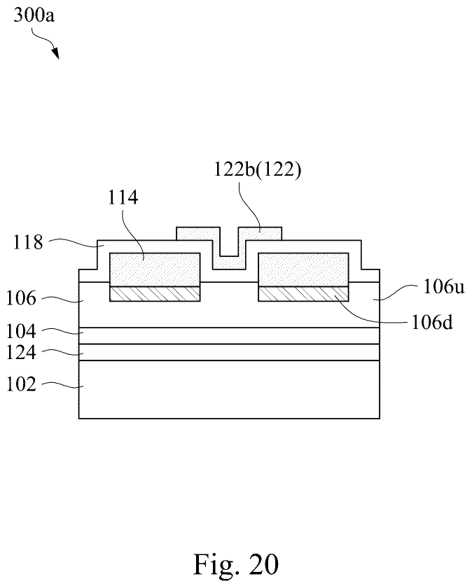

FIG. 20 is a field effect transistor 300a similar to the field effect transistor 300 in FIG. 19, except for the field effect transistor 300b further comprising a gate electrode 124 between the substrate 102 and the first gate dielectric layer 104. For example, the gate electrode 124 extends along an entire bottom surface 104b of the first gate dielectric layer 104. The gate electrode 112c can be referred to as a global gate since the gate electrode 112c can have a length L1 greater than a spacing S1 between sidewalls SW1, SW2 of the two neighboring second portions 110b of the first conductive layer 110 facing away from each other. In some embodiments, the gate electrode 112c overlaps the doped region 106dc.

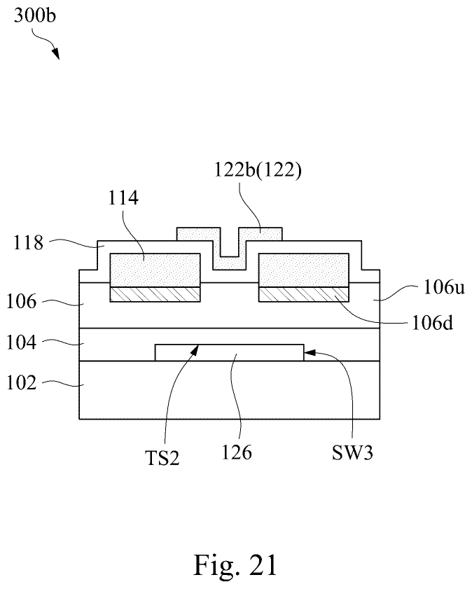

FIG. 21 is a field effect transistor 300b similar to the field effect transistor 300 in FIG. 19, except for the field effect transistor 300b further comprising a gate electrode 126 between the substrate 102 and the first gate dielectric layer 104. For example, the gate electrode 126 overlaps a region of the semiconductor layer 106 between the two neighboring ones of the second portion 110b of the first conductive layer 110. That is, the gate electrode 126 has opposite sidewalls SW4 and a top surface TS2 covered by the first gate dielectric layer 104. The gate electrode 126 can be referred to as a local gate.

Based on the above discussions, it can be seen that the present disclosure in various embodiments offers advantages. It is understood, however, that other embodiments may offer additional advantages, and not all advantages are necessarily disclosed herein, and that no particular advantage is required for all embodiments. One advantage is that by performing a plasma treatment to source/drain contact area of a semiconductor layer prior to depositing a conductive layer and thus can provide improved and smooth interface between the conductive layer and the channel (i.e., the source/drain contact area of the semiconductor layer). Another advantage is that therefore, the ambipolar effect in the p-type semiconductor transistors can be reduced or suppressed. Drain current can thus remain low in the off-state.

In some embodiments, a method of forming a field effect transistor comprises the following steps. A gate dielectric layer and a semiconductor layer are formed over a substrate in sequence. A photoresist layer is formed over the semiconductor layer. A plasma treatment is performed to the semiconductor layer to form a doped region and an undoped region laterally adjoining the doped region of the semiconductor layer using a gas. A conductive layer is formed over the doped region of the semiconductor layer and the photoresist layer. The photoresist layer is lifted off. In some embodiments, the gas used in the plasma treatment comprises SF₆, CH₂F₂, BCl₃, Ar, N₂, or a combination thereof. In some embodiments, the semiconductor layer comprises SnOx, CuOx, NiOx, or a combination thereof. In some embodiments, the doped region and the undoped region have top surfaces at different heights. In some embodiments, the doped region comprises F—Sn bonding. In some embodiments, the doped region comprises S—Sn bonding. In some embodiments, the method further comprises after performing the plasma treatment to the semiconductor layer, annealing the semiconductor layer, and after annealing the semiconductor layer, the doped region comprises F—Sn bonding. In some embodiments, t he method further comprises after performing the plasma treatment to the semiconductor layer, annealing the semiconductor layer, and after annealing the semiconductor layer, the doped region comprises S—Sn bonding.

In some embodiments, a method of forming a field effect transistor comprises the following steps. A gate dielectric layer and a semiconductor layer are formed over a substrate in sequence. A photoresist layer is formed over the semiconductor layer. A doped region is formed in the semiconductor layer while leaving an undoped region in the semiconductor layer laterally adjoining the doped region. A conductive layer is formed over the doped region and the undoped region of the semiconductor layer of the semiconductor layer. The conductive layer is patterned to leave the conductive layer overlapping the doped region of the semiconductor layer. In some embodiments, forming the doped region in the semiconductor layer comprises performing a plasma treatment to the semiconductor layer using SF₆, CH₂F₂, BCl₃, Ar, N₂, or a combination thereof. In some embodiments, the doped region is thinner than the undoped region. In some embodiments, the semiconductor layer is a metal oxide layer. In some embodiments, the semiconductor layer is p-type.

In some embodiments, a field effect transistor comprises a substrate, a first gate dielectric layer, a semiconductor layer and a first conductive layer. The first gate dielectric layer is over the substrate. The semiconductor layer is over the first gate dielectric layer, wherein the semiconductor layer comprises a doped region and an undoped region laterally adjoining the doped region. The first conductive layer is over the semiconductor layer, wherein the first conductive layer has a bottom surface lower than a top surface of the undoped region of the semiconductor layer. In some embodiments, the doped region comprises F—Sn bonding, S—Sn bonding or a combination thereof. In some embodiments, the field effect transistor further comprises a gate electrode between the substrate and the first gate dielectric layer, wherein the gate electrode overlaps the doped region of the semiconductor layer. In some embodiments, the first conductive layer non-overlaps the doped region of the semiconductor layer. In some embodiments, the field effect transistor further comprises a second gate dielectric layer over the first conductive layer and a second conductive layer over the second gate dielectric layer. In some embodiments, the field effect transistor further comprises a gate electrode between the substrate and the first gate dielectric layer, wherein the gate electrode overlaps the doped region of the semiconductor layer. In some embodiments, the substrate comprises silicon, glass or plastic.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a field effect transistor, comprising:
forming a gate dielectric layer and a semiconductor layer over a substrate in sequence;
forming a photoresist layer over the semiconductor layer;
performing a plasma treatment to the semiconductor layer to form a doped region and an undoped region laterally adjoining the doped region of the semiconductor layer using a gas;
forming a conductive layer over the doped region of the semiconductor layer and the photoresist layer; and
lifting off the photoresist layer.

2. The method of claim 1, wherein the gas used in the plasma treatment comprises SF₆, CH₂F₂, BCl₃, Ar, N₂, or a combination thereof.

3. The method of claim 1, wherein the semiconductor layer comprises SnOₓ, CuOₓ, NiOₓ, or a combination thereof.

4. The method of claim 1, wherein the doped region and the undoped region have top surfaces at different heights.

5. The method of claim 1, wherein the doped region comprises F—Sn bonding.

6. The method of claim 1, wherein the doped region comprises S—Sn bonding.

7. The method of claim 1, further comprising:
after performing the plasma treatment to the semiconductor layer, annealing the semiconductor layer, and after annealing the semiconductor layer, the doped region comprises F—Sn bonding.

8. The method of claim 1, further comprising:
after performing the plasma treatment to the semiconductor layer, annealing the semiconductor layer, and after annealing the semiconductor layer, the doped region comprises S—Sn bonding.

9. A method of forming a field effect transistor, comprising:
forming a gate dielectric layer and a semiconductor layer over a substrate in sequence;
forming a photoresist layer over the semiconductor layer;
forming a doped region in the semiconductor layer while leaving an undoped region in the semiconductor layer laterally adjoining the doped region;
forming a conductive layer over the doped region and the undoped region of the semiconductor layer of the semiconductor layer; and
patterning the conductive layer to leave the conductive layer overlapping the doped region of the semiconductor layer.

10. The method of claim 9, wherein forming the doped region in the semiconductor layer comprises:
performing a plasma treatment to the semiconductor layer using SF₆, CH₂F₂, BCl₃, Ar, N₂, or a combination thereof.

11. The method of claim 9, wherein the doped region is thinner than the undoped region.

12. The method of claim 9, wherein the semiconductor layer is a metal oxide layer.

13. The method of claim 12, wherein the semiconductor layer is p-type.

14. A field effect transistor, comprising:
a substrate;
a first gate dielectric layer over the substrate;
a semiconductor layer over the first gate dielectric layer, wherein the semiconductor layer comprises a doped region and an undoped region laterally adjoining the doped region; and
a first conductive layer over the semiconductor layer, wherein the first conductive layer has a bottom surface lower than a top surface of the undoped region of the semiconductor layer.

15. The field effect transistor of claim 14, wherein the doped region comprises F—Sn bonding, S—Sn bonding or a combination thereof.

16. The field effect transistor of claim 14, further comprising:
a gate electrode between the substrate and the first gate dielectric layer, wherein the gate electrode overlaps the doped region of the semiconductor layer.

17. The field effect transistor of claim 14, wherein the first conductive layer non-overlaps the doped region of the semiconductor layer.

18. The field effect transistor of claim 14, further comprising:
a second gate dielectric layer over the first conductive layer; and
a second conductive layer over the second gate dielectric layer.

19. The field effect transistor of claim 18, further comprising:
a gate electrode between the substrate and the first gate dielectric layer, wherein the gate electrode overlaps the doped region of the semiconductor layer.

20. The field effect transistor of claim 18, wherein the substrate comprises silicon, glass or plastic.
